(19) United States
(12) Patent Application Publication
(10) Pub. No.: US 2008/0285165 A1
(43) Pub. Date: Nov. 20, 2008

(54) Thin film filter system and method

(76) Inventors: Kuohua (Angus) Wu, Tucson, AZ (US); Al Davis, Philomath, OR (US); David L. Erickson, Philomath, OR (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/803,239

(22) Filed: May 14, 2007

(51) Int. Cl. H01L 21/70

(52) U.S. Cl. 359/885; 438/57; 257/E21.535

(57) ABSTRACT

Various embodiments of a system and method for producing a thin film filter are disclosed.

### BACKGROUND

A photospectrometer is an instrument used for measuring wavelengths of light digitally, so that shades of color can be accurately detected. One type of filter that can be used with a solid state photospectrometer is a Fabry-Perot filter. Using current fabrication methods it can be relatively complicated and costly to fabricate a photospectrometer having an array of Fabry-Perot filters of unique thicknesses affixed atop addressable photodiodes due to multiple etching and deposition steps used to obtain an array of transparent layers with different thicknesses.

### BRIEF DESCRIPTION OF THE DRAWINGS

Various features and advantages of the present disclosure will be apparent from the detailed description which follows, taken in conjunction with the accompanying drawings, which together illustrate, by way of example, features of the present disclosure, and wherein:

FIG. 1 is a partial cross-sectional view of a solid state photospectrometer comprising an array of photodiodes, with each photodiode having a unique light filter;

FIG. 2 is a partial cross-sectional view of a typical Fabry-Perot filter;

FIG. 3 is a partial cross-sectional view of one embodiment of a thin film Multi-Lay optical Coating (MLC) filter;

FIG. 4 is a partial cross-sectional view of one embodiment of a wedge shaped linearly variable thin film multi-layer optical coating filter having a wedge profile;

FIG. 5 is a partial cross-sectional view of one embodiment of a solid state photospectrometer comprising an array of photodiodes having a wedge shaped linearly variable thin film multi-layer optical coating filter;

FIG. 6 is a graph of light transmission versus wavelength for three discrete regions of an embodiment of a wedge shaped linearly variable filter;

FIG. 7 illustrates one embodiment of a wedge coating system and method that can be used to produce a linearly variable filter in accordance with the present disclosure, showing the wedge coating substrate as it is approaching the target; and

FIG. 8 illustrates the wedge coating system and method shown in FIG. 7, showing the wedge coating substrate after it passes the target.

### DETAILED DESCRIPTION

Reference will now be made to exemplary embodiments illustrated in the drawings, and specific language will be used herein to describe the same. It will nevertheless be understood that no limitation of the scope of the present disclosure is thereby intended. Alterations and further modifications of the features illustrated herein, and additional applications of the principles illustrated herein, which would occur to one skilled in the relevant art and having possession of this disclosure, are to be considered within the scope of this disclosure.

The present disclosure relates to solid-state light filters, such as are frequently used with photospectrometers. As noted above, photospectrometers are frequently used in the printing arts to calibrate digital color printing systems and to help measure the color match quality of printed output. For accurate color detection and calculation, it is desirable that the photospectrometer detect numerous narrow light transmission bands.

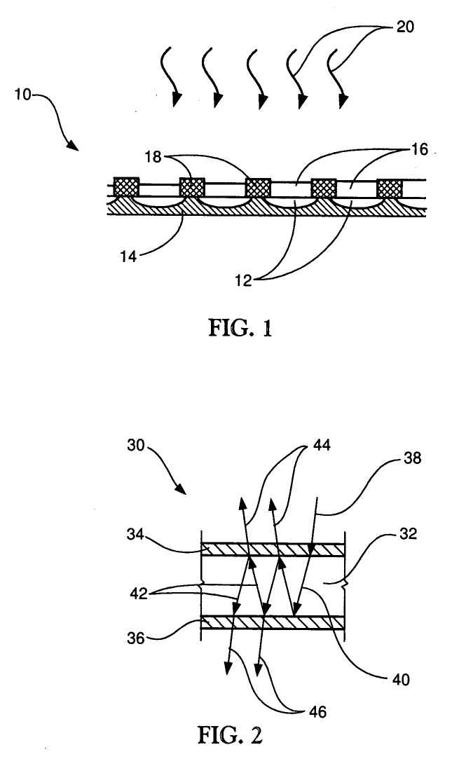

One common approach for creating a photospectrometer that detects a series of high and narrow transmission bands is to use an array of filters positioned over photodiodes. In such a photospectrometer the filters are integrated with the photodiode array. Shown in FIG. 1 is one embodiment of a photospectrometer 10 having a plurality of photodiodes 12 mounted on a substrate 14. Each photodiode is provided with a discrete filter 16 that allows only a certain wavelength band of the incident light 20 to be passed to that photodiode, so that light intensity across a spectrum is detected. In other words, each photodiode can detect the intensity of light of a given wavelength depending upon the characteristics of its particular filter. Adjacent filters are separated by spacer material 18 that prevents light leakage between adjacent photodiodes.

One type of filter that can be used with this type of device is a Fabry-Perot filter. Fabry-Perot filters are widely used in telecommunications, lasers and spectroscopy for controlling and measuring the wavelength of light. One embodiment of a Fabry-Perot filter 30 is shown in FIG. 2. This filter includes a transparent layer 32 that is sandwiched between two parallel, partially reflective layers 34 and 36. The transparent layer 32 that separates the partially reflective layers 34, 36 is frequently a dielectric material, such as silicon dioxide, aluminum oxide, titanium dioxide, zinc oxide, tellurium oxide, etc. A variety of materials can be used for the partially reflective layers, including metals such as aluminum, copper, silver, gold, etc. Metals are generally good reflectors, though they differ in absorption characteristics at different wavelengths. Silver is frequently used for the metal layers in a Fabry-Perot filter because silver has relatively high reflectivity and exhibits less absorption than some other metals in the visible spectrum. The thickness and nature of the top partially reflective metal layer (i.e. what kind of metal) will initially determine what wavelengths of light will enter the transparent (e.g. dielectric) layer, and the transmission efficiency of the filter. The transparent material that separates the reflective surfaces is often chosen to maintain stable mirror-to-mirror distances, and to keep stable frequencies even when the temperature varies.

Incoming light 38 that passes through the top partially reflective layer is initially refracted, as indicated at 40, and then reflects internally between the two partially reflective layers, as indicated at 42. Through interference between the internally reflecting light, certain wavelengths will be absorbed or reflected out of the filter, as indicated at 44, while light of other wavelength(s) will be passed through the bottom partially reflective layer, as indicated at 46. The varying transmission function of a Fabry-Perot filter is caused by interference between the multiple reflections of light between the two reflecting surfaces. Constructive interference occurs if the transmitted beams are in phase, and this corresponds to a high-transmission peak of the filter. If the transmitted beams are out-of-phase, destructive interference occurs, and this corresponds to a transmission minimum. Whether the multiply-reflected beams are in-phase or not depends on the wavelength of the light, the angle the light travels through the filter, the thickness of the dielectric layer, and the refractive index of the dielectric layer. Ultimately, only a certain wavelength band of light will pass through the bottom metal layer.

The transmission spectrum of a Fabry-Perot filter as a function of wavelength exhibits peaks of large transmission corresponding to resonances of the filter. The shape of the wavelength peak that is passed by a given Fabry-Perot filter is quantified by a characteristic called finesse. Fabry-Perot filters with high finesse show sharper transmission peaks with lower minimum transmission coefficients. However, it can be difficult to obtain high finesse (high transmission and narrow bandwidth) in a standard Fabry-Perot filter. If a given filter has low transmission and wide bandwidth, there will be a smaller transmission band in the visible spectrum. In order to achieve high finesse, it is desirable that the partial reflective layers should also have high reflectivity. Thicker metallic layers will provide better internal reflectivity, but thicker metallic layers will also absorb light. Thinner metallic layers allow more light transmission, but thin metallic layers provide less internal reflectivity, which increases the need for high finesse. Consequently, high finesse in a Fabry-Perot filter is difficult to obtain because thicker metal layers will provide a narrower bandwidth but will reduce transmission, while thinner metal layers increase transmission of light, but provide a wider bandwidth due to lower internal reflectivity. It is thus difficult to obtain both high transmission and a narrow bandwidth with a Fabry-Perot filter using metals as the partially reflective layers.

Additionally, using an array of fixed Fabry-Perot filters over photodiodes presents some other undesirable aspects. As is apparent from FIG. 1, a discrete filter of a particular thickness is used for each desired wavelength. Consequently, this approach requires multiple etching and deposition steps to obtain an array of transparent spacer layers with different thicknesses. Where the total number of desired transmission bands is 2ₙ , the number of etching and deposition process cycles will be n+1. Thus, for example, if detection of 16 discrete wavelength bands is desired, the value of n will be 4 (because 2⁴=16), and the total number of deposition/etch fabrication cycles for the Fabry-Perot filter layers will thus be 5, with each cycle involving multiple individual steps. This adds significant time and cost to the fabrication of this type of photospectrometer.

Fabry-Perot filters with silver reflective layers are also known to have relatively low transmission, especially in the blue portion of the spectrum, and tend to produce a second harmonics peak in the red wavelength band, which can add noise to the output signal of the photospectrometer. Additionally, since these filters include metal layers on their top and bottom, the bottom metal layer can contaminate the integrated photodiode array, and the top metal layer generally requires additional insulating layers to protect against humidity and human handling.

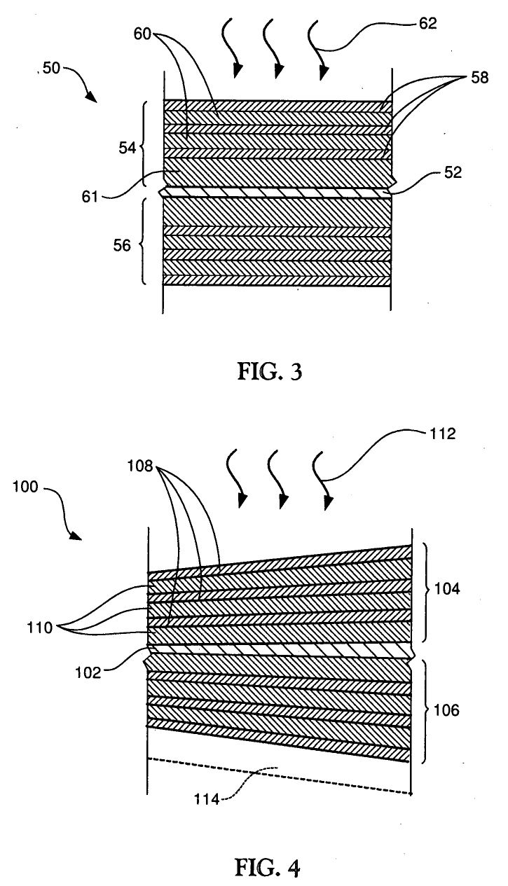

Advantageously, the inventors have developed a linearly variable wedge-shaped thin film multi-layer optical coating (MLC) filter that has some advantages over the standard Fabry-Perot filter. A non-wedge-shaped embodiment of such a thin film filter 50 is shown in FIG. 3. The filter comprises one and only one partially reflective metal layer 52 that is sandwiched between two transparent layers 54, 56. Each transparent layer includes alternating layers of dielectric material of different thicknesses and having different properties. For example, each transparent layer can have three layers 58 of a first dielectric material, alternating with three layers 60, 61 of a different dielectric material. The top and bottom transparent layers are identical, though inverted from each other. As with a Fabry-Perot filter, undesired wavelengths of the incident light 62 are filtered out through interference, depending upon the thickness of the different dielectric layers, and their refractive indices. Ultimately, a certain wavelength band of light will exit the bottom transparent layer 56.

In one embodiment, the inventors prepared a thin film multi-layer optical coating filter like that shown in FIG. 3 having six alternating layers of two different dielectric materials (e.g. one material having a refractive index that is higher than the refractive index of the other) in each transparent layer 54, 56. In this embodiment, the first third and fifth layers 58 were of titanium dioxide (TiO₂) and had a thickness of about 51.46 nm. The second and fourth layers 60 were of silicon dioxide (SiO₂) and had a thickness of about 86.69 nm. The sixth layer 61 of each transparent layer (the layer positioned adjacent to the partially reflective metal layer) was of silicon dioxide (SiO₂) and had a thickness of about 152.58 nm. The metal layer 52 was a layer of aluminum (Al) having a thickness of about 14 nm.

This non-wedge shaped filter passed a high, narrow band of light at the 500 nm wavelength range. A plot of the pass band curve is shown at 152 in FIG. 6. As can be seen, this filter provided a peak transmission efficiency of about 85% at this wavelength.

In order to provide a linearly variable filter, the inventors have produced a thin film multi-layer optical coating filter like that of FIG. 3 in a wedge profile, as shown in FIG. 4. In the wedge-shaped thin film multi-layer optical coating filter 100 the metal layer 102 and each transparent layer 104,106 have a wedge profile that is thinner toward one end and thicker toward the other. In one embodiment, the inventors have found that a wedge profile providing about a 45% thickness increase from one end of the filter the other provides sufficient variability. In other words, the thickness of the filter at the thick end will be about 45% greater than the thickness at the thin end. This variation in thickness is only one example. Other wedge profiles can also be used. It should also be noted that the wedge profile is greatly exaggerated in FIG. 4 for illustrative purposes.

All of the layers of the filter 100 linearly increase in thickness in the same direction from one end of the filter to another, which can be referred to as a wedge direction. The wedge profile provides a linearly varying filter because the wavelength of light that is passed varies depending upon the thickness of all of the layers. Because all of the layers linearly vary in thickness, the wavelength of light that will pass through the filter will vary linearly from one edge of the filter to another. This wedge profile allows sufficient variability to selectively allow passage of light throughout the visible spectrum. It will be apparent, however, that this type of filter can be used to filter light that is outside the visible spectrum.

This linearly variable light filter 100 thus includes one and only one partially reflecting layer 102 having a wedge-shaped profile. The first transparent layer 104 is disposed atop the partially reflecting layer, and the second transparent layer 106 is disposed on the bottom of the partially reflecting layer. A transparent substrate 114 can be provided adjacent to either or both of the top and bottom of the filter. Suitable materials for the partially reflecting layer include metals such as aluminum, silver, copper, gold, nickel, tin, chromium, etc. Other reflective materials can also be used. Silver and aluminum are considered suitable materials for the partially reflective layer. Aluminum is desirable because of its low cost and ease of use in semiconductor fabrication techniques. Silver is desirable because of its relatively high reflectivity and other optical properties. In general, metals are suitable because they tend to be good reflectors in the visible and infrared ranges, though metals can present various absorption characteristics in different wavelength ranges. For example, copper shows some light absorption below 500 nm, while silver does not absorb light in the visible range to the same extent as copper. Consequently, different metals can be used for different wavelength targets. Those of skill in the art will be able to select a suitable material for the partially reflective layer.

A transparent substrate (e.g. glass, silicon, etc.) can be disposed below the second transparent layer 106 and/or above the first transparent layer 104. The use of a substrate layer can be convenient for fabrication. For example, the wedge-shaped filter can be fabricated upon a glass substrate that will provide a window or lens into a photospectrometer chip. Alternatively, the thin film multi-layer optical coating can be fabricated directly atop an array of photodiodes as part of a photospectrometer, the array serving as the substrate. Other substrates can also be used.

Each transparent layer comprises at least three layers of material of differing characteristics, each layer having a wedge-shaped profile oriented in the wedge direction. In one embodiment, the transparent layers can each comprise at least three layers of dielectric material. The number of layers in each transparent layer can vary, from as few as three layers, to any number of layers. The inventors have found that fewer layers tends to decrease the resolution of the filter, while more layers increases internal reflectivity and narrows the bandwidth. A greater number of layers also appears to enhance transmission and reduces noise, though it also increases fabrication cost. The inventors believe that more than 22 layers begins to become impractical. Suitable dielectric materials for the transparent layers include titanium dioxide (TiO₂), silicon dioxide (SiO₂), tantalum oxide (TaO), niobium oxide (NbO), aluminum oxide (AlOx), zinc oxide (ZnOx), tellurium oxide (TeOx), hafnium oxide (HfOx), etc. Other materials can also be used. Those of skill in the art will be able to select suitable materials for the transparent layers.

The inventors have found that six dielectric layers in each transparent layer is a workable configuration (thus producing a thin film multi-layer optical coating having 13 total layers—six layers on top, one metal layer, and six layers on the bottom). This configuration is shown in FIG. 4. The top transparent layer 104 includes first, third, and fifth layers 108 of a first dielectric material, and second, fourth and sixth layers 110 of a second dielectric material. The top and bottom transparent layers 104, 106 are identical, but inverted relative to each other. That is, the material types and thicknesses occur in the reverse order in the bottom layer, compared to the top layer, when each is considered from the top down. Incident light 112 is selectively passed through the filter depending upon the thickness of all of the layers at a given point along the filter.

As discussed above with respect to the non-wedge-shaped embodiment of FIG. 3, the first and second transparent layers can each comprise alternating layers of two different dielectric materials of two different thicknesses, and a third thickness of one of the two dielectric materials in a layer adjacent to the partially reflecting metal layer. In one embodiment this can comprise six alternating layers of two different dielectric materials in each transparent layer. Alternatively, the thicknesses of the respective dielectric layers can vary randomly within each transparent layer. That is, rather than two or three discrete thicknesses for the layers of alternating material, each layer can have a thickness that differs from each of the others. It will be apparent that, using a six layer configuration like that shown in FIG. 3, but having a wedge shaped profile as shown in FIG. 4 can provide the actual combination of layer thicknesses discussed above (with respect to FIG. 3) at one discrete location along the wedge profile. These thicknesses will decrease proportionally in one direction from that location, and increase proportionally in an opposite direction from the location. In one embodiment, the linearly variable filter having a wedge profile can have a partially reflecting metal layer of aluminum with a thickness that ranges from about 10 nm to about 30 nm, and first and second transparent layers of alternating layers of titanium dioxide (TiO₂), silicon dioxide (SiO₂), each stack having a total thickness that ranges from about 30 nm to about 150 nm from one end of the wedge shaped filter to the other.

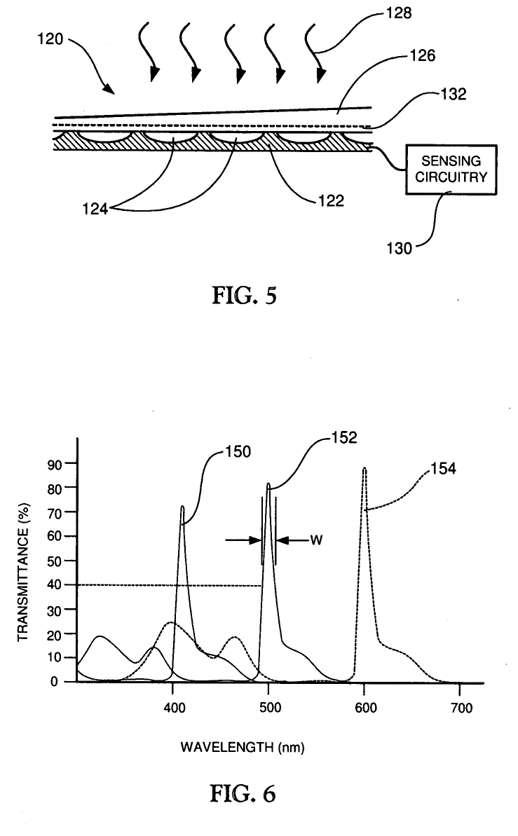

Advantageously, this wedge-shaped design can be produced using a single deposition process, and provides good film quality and accurate thickness control, while also reducing deposition time and cost compared to a standard Fabry-Perot filter. As shown in FIG. 5, when this type of filter 126 is coupled with an array of photodiodes 124, it can provide a photospectrometer 120 with multiple wavelength sensitivity using one continuous filter, rather than having separate discrete filters for each photodiode. The photospectrometer generally includes a substrate 122 having a plurality of photodiodes 124 disposed thereon. Each photodiode is electrically coupled to sensing circuitry 130, the circuitry configured to receive a signal representative of light intensity sensed by the photodiode. Incident light 128 is filtered by the variable thin film filter 126, so that each photodiode receives a different wavelength band of light. As suggested above, in one embodiment, the wedge shaped filter can be disposed upon a transparent substrate 132, this transparent substrate overlying the array of photodiodes.

The linearly variable light filter is disposed over the array of photodiodes, and, as described above, includes one and only one partially reflecting metal layer having a wedge profile, with a first transparent layer as described above disposed on top of the metal layer, and a second transparent layer disposed on the bottom of the metal layer. Each transparent layer includes at least two dielectric layers of differing materials, and each dielectric layer has a wedge-shaped profile oriented in the wedge direction. This configuration allows a different wavelength band of light to be provided to each photodiode, depending upon the total thickness of the linearly variable light filter at the position of the particular photodiode.

The inventors have found that the linearly variable thin film multi-layer optical coating filter provides relatively high transmission of light. For example, as shown in FIG. 6, a linearly variable filter as described herein can provide wavelength peaks at various desired wavelengths. It can be seen that the transmission of light at each wavelength peak is quite high. The inventors have found that this linearly variable filter will pass from about 75% to about 90% of light over the entire visible spectrum, the lower transmission being toward the blue end of the scale. For example, one embodiment of a photospectrometer provided with a linearly variable MLC as described herein can provide a peak 150 at a wavelength of around 400 nm, with another peak 152 at about 500 nm. Additional transmission peaks can also be provided, such as the peak 154 at around 600 nm. Each of these peaks provides more than 70% transmission efficiency. In contrast, a typical Fabry-Perot filter tends to provide only about 20% to 50% transmission in the visible spectrum.

Another feature ofthis filter configuration is that the bandwidth at each desired wavelength (i.e. the width W of each peak on the transmittance graph of FIG. 6) can be selected by varying the characteristics (i.e. the materials and layer thicknesses) of the thin film multi-layer optical coating. The bandwidth W is typically measured as the width of the transmission peak at a level that is half of the peak value. This is referred to as the full-width half max (FWHM) value. In FIG. 6, for the 500 nm peak 152m having a maximum transmission of about 80%, the FWHM value is the width of the peak measured at about the 40% level, as shown. Each different film thickness design (i.e. combination of layer thicknesses) will produce a different FWHM bandwidth. This approach can allow one to adjust the design to narrow the bandwidth without a trade off in transmission performance. It is to be noted that changes in the overall wedge profile do not significantly affect the targeted FWHM. The inventors have found that in the wedge shaped thin film multi-layer optical coating disclosed herein the bandwidth can be adjusted from about 5 nm to about 30 nm FWHM without a loss of transmission efficiency through careful selection of the thin film materials and thicknesses. The Fabry-Perot approach, on the other hand, only allows adjustment of the bandwidth from about 20 nm to about 40 nm, and also involves a tradeoff in transmission efficiency (i.e. less transmission as the bandwidth narrows).

The linearly variable thin film multi-layer optical coating filter with a wedge-shaped profile allows infinite transmission bands to be chosen without requiring multiple etching and deposition steps in the filter fabrication. The thin film multi-layer optical coating filter can be produced using aluminum for the metal layer, which is less expensive and more fabrication-friendly than silver. This configuration also promotes good film quality and accurate thickness control, and reduces the quantity of deposition materials needed, and the fabrication time and cost compared to other methods.

This configuration also provides high transmission throughout the visible spectrum, relatively narrow bandwidth peaks (i.e. providing high finesse) and a greater range of adjustability in bandwidth. Another desirable aspect of the linearly variable thin film multi-layer optical coating filter disclosed herein is that it does not produce a second order harmonics peak, as does a standard Fabry-Perot filter. Additionally, since the wedge-shaped filter includes transparent dielectric layers on top and on the bottom, the filter naturally has excellent electrical isolation from photodiode circuitry underneath, and the upper dielectric layer provides protection from oxidation, humidity, and potential adhesion with other structures.

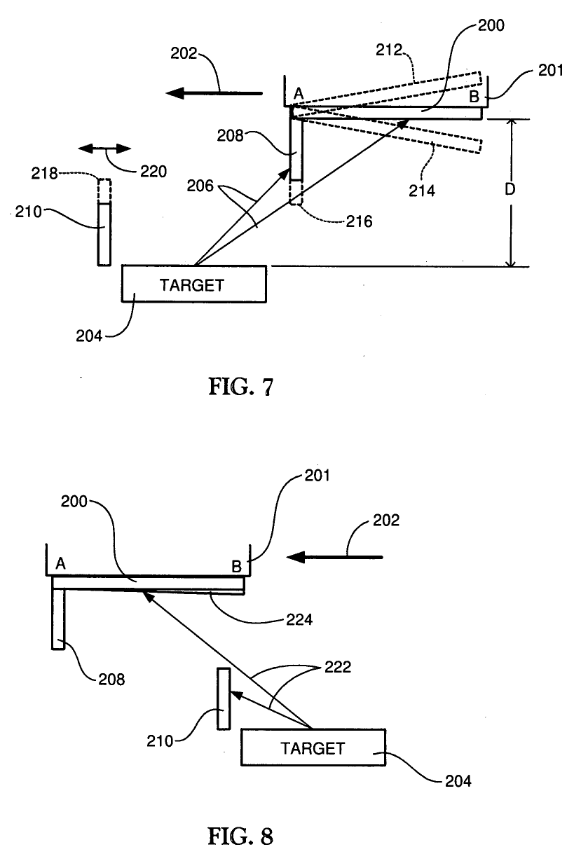

A system and method for producing a wedge shaped thin film multi-layer optical coating filter as disclosed herein is illustrated in FIGS. 7 and 8. This method can be practiced with drum-type or in-line type sputter coating machines. A substrate 200 for the linear variable filter is attached to a moveable mount 201 within the coating machine. The material of the substrate can be any of a variety of materials. For example, the substrate can be a clear material, such as glass, or it can be a semiconductor material, such as silicon. For example, a semiconductor substrate having photodiodes already etched upon it as a photospectrometer can be placed in the sputter coating machine to have a thin film filter deposited directly upon it. Other substrate materials can also be used. The mount with the substrate attached is then repeatedly caused to move substantially linearly, in the direction of arrow 202, past a stationary target 204, which sends out the sputter coating material, represented by rays 206 (220 in FIG. 8), as the substrate passes. The coating material is deposited upon the substrate in small layers with each pass, thus gradually building up a film of the coating material.

As is well known to those of skill in the semiconductor fabrication arts, a stream or cloud of sputter coating material can be produced by directing a plasma stream or the like toward a target made of the material with which it is desired to coat a substrate. The target is the source of the base sputter coating material, and can be a metal or a non-metal, such as aluminum, copper, gold, silver, titanium, silicon, etc. The plasma stream liberates individual atoms of the target material, and causes them to stream toward the substrate. The thickness of the thin film can be controlled by the number of passes that the substrate makes past the target, and the intensity of the stream of coating material.

Reactants can also be introduced into the stream of coating material to change the chemical composition of the coating between the time that the base coating material leaves the target and when it actually lands upon the substrate. For example, if it is desired that the coating be of an oxide (e.g. titanium dioxide (TiO₂)), an oxygen source (e.g. a jet of oxygen gas) can be positioned near the target so that the base coating material (e.g. titanium) can react with the oxygen as the stream moves toward the substrate.

The wedge coating system and method illustrated in FIGS. 7 and 8 includes a number of features that allow the thickness of the coating to linearly vary from one edge of the substrate to the other, so as to produce a wedge coating profile. Additionally, these features can be adjusted or manipulated in various ways in order to vary the relative thickness of the respective ends of the wedge coating. For example, positioned at the forward end (relative to the direction of motion) of the substrate 200 is a mask 208, which moves with the substrate and creates a shadow to block some of the coating material 206 with each pass of the substrate. The mask can be oriented to be substantially perpendicular to the substrate as shown, or it can be oriented in different ways.

It will be apparent that the quantity of coating material that is blocked by the mask 208 will gradually decrease as the substrate 200 nears and passes the target 204. When the substrate is relatively far away from the target, all of the flux will be blocked at first. The B end of the substrate will become exposed to the flux first, with more of the substrate gradually becoming exposed as the substrate approaches the target. When the substrate is directly opposite the target and the mask has passed the far end of the target, substantially the entire substrate will be exposed to the coating flux, and the mask will no longer block the flux. This configuration causes more material to be deposited on the far end of the substrate (labeled “B”) than on the near end (labeled “A”) with each pass, thus causing the coating material to become thicker toward the B end with each pass. The wedge profile that this coating system and method produces is shown in FIG. 8, where a thin film 224 is shown deposited upon the substrate, having a greater thickness at the B end than at the A end. It is to be understood that the thickness of the thin film and the variation in the wedge profile are both greatly exaggerated in FIG. 8 for illustrative purposes.

As an additional feature for varying the wedge profile, the height of the mask 208 can be varied. This is shown in dashed lines at 216 in FIG. 7. A mask that is taller relative to the substrate will cast a larger shadow, while a mask that is shorter will cast a smaller shadow. Variation in the height of the mask can thus be used as one method of varying the wedge profile. For example, if it is desired that the wedge profile be less dramatic (i.e. less variation in thickness from one end of the substrate to the other) the mask can be made shorter, and vice versa.

As another method of varying the wedge profile, a shield 210 can be placed on the downstream side (relative to the direction of motion of the substrate) of the target 204 to block coating material from being deposited on the substrate 200 after the substrate passes, as illustrated in FIG. 8. After the substrate passes the target, some streams 222 of coating material will be blocked by the shield, while others will not. As is apparent from this figure the portions of the coating stream that are tending toward the A end of the substrate are blocked more than those tending toward the B end. This also reduces the amount of material that is deposited toward the A side with each pass, and thereby causes the thin film to be thicker at the B end than at the A end.

The shield 210 can be adjusted in at least two ways to contribute to the variation in the wedge profile. First, the height of the shield can be varied, as indicated at 218 in FIG. 7. Raising the height of the shield will tend to block more coating flux with each pass of the substrate, causing less material to be deposited toward the A end relative to the B end. It is to be understood that the height of the shield and the height of the mask 208 should be correlated so that there is no mechanical interference between these two structures when the coating machine is in operation.

In addition to varying the height of the shield 210, the position of the shield relative to the target 204 can also be varied. This variation in position is indicated by the arrow 220 in FIG. 7. When the shield is closer to the target, a greater amount of coating material flux (indicated by arrows 222 in FIG. 8) will be blocked from hitting the substrate 200 after the substrate passes the target. This will further reduce the amount of material that is deposited toward the A side with each pass, and thereby contribute toward making the thin film thicker at the B end than at the A end.

The wedge coating profile can also be adjusted in several other ways. As shown in FIG. 7, the substrate 200 can be tilted, as indicated by the dashed line positions 212 and 214. Tilting of the substrate can place the B end either nearer or farther away from the target 204 with each pass, thus either increasing or decreasing the exposure of the substrate. If the substrate is tilted with the B end up, as indicated at 212, a smaller amount of material will be deposited toward the B end with each pass, making the wedge profile more uniform in thickness, the thickness change being less drastic from the A end to the B end. On the other hand, if the substrate is tilted with the B end down, as indicated at 214, this will increase the exposure of the B end with each pass, making the wedge profile more drastic.

As another method for adjusting the wedge profile, the distance D (shown in FIG. 7) between the target 204 and the substrate 200 can also be varied. Increasing the distance D will tend to diminish the variation in wedge thickness (i.e. make the film thickness more uniform), while decreasing the distance will tend to increase the variation in the thickness of the thin film from one end to the other of the substrate. Decreasing the distance between the target and the substrate will also tend to reduce the effect of gravity on the stream of sputter coating material. If the substrate is closer to the target, more of the material will be deposited, rather than falling downward before contacting the substrate.

Any or all of the above types of changes can be made to adjust the variation in the thickness of the material that is sputter coated onto the substrate in order to vary the wedge profile of the thin film. The end result is a thin film of one or more layers that has a linearly varying wedge profile that is thicker toward one end and thinner toward the other end. This method can be used to produce a thin film filter having one metal layer with a multi-layer transparent layer above and below the metal layer. Such a filter can be used to selectively filter out wavelengths of light, such as to obtain discrete wavelength ranges for sensing with a photospectrometer. Since the wavelength filtering properties of this type of filter vary with the thickness of the respective layers, the linearly varying thickness of the wedge profile allows one filter to pass a whole range of wavelengths depending upon a position along the filter, rather than requiring multiple filters for the same purpose.

Advantageously, the metal layer and the dielectric layers of the linear variable filter can all be deposited in one process using this wedge coating technique. For example, to produce a linearly varying filter like that shown in FIG. 4, a substrate can be placed in a drum coating machine and provided first with six alternating layers of two different dielectric materials (e.g. TiO₂ and SiO₂)) to produce a first dielectric stack, each layer having a wedge profile of a selected thickness range. This can involve depositing a first layer using a target of titanium with oxygen injection, then depositing a second layer using a target of silicon with oxygen injection, then titanium again, then silicon again, and so on.

Without removing the substrate from the drum coating machine, a metal layer can then be deposited in a wedge profile, after which six alternating layers of the previous two dielectric materials can be deposited upon the metal layer, to provide the second dielectric stack. Fabrication of the wedge shaped filter via a single deposition process in accordance with the method disclosed herein contributes to robustness, better thickness control, and lower cost for the wedge-shaped filter. Additionally, as noted above, the substrate can be a clear material (e.g. glass) that is then attached to a semiconductor or other device, or the substrate can be a semiconductor device itself, having components (e.g. photodiodes) already formed upon it. In this way, a solid state photospectrometer can have a linearly varying filter deposited directly upon its sensor array.

It is to be understood that the above-referenced arrangements are illustrative of the application of the principles disclosed herein. It will be apparent to those of ordinary skill in the art that numerous modifications can be made without departing from the principles and concepts of this disclosure, as set forth in the claims.

What is claimed is:

1. A method for fabricating a thin film filter, comprising:
repeatedly moving a substrate, having a forward end, substantially linearly past a source of sputter coating material; and
positioning a shadow mask adjacent to the forward end of the substrate, to selectively block the coating material with each pass of the substrate, whereby the sputter coating material is deposited on the substrate in a layer having a wedge profile.

2. A method in accordance with claim 1, further comprising adjusting a height of the mask relative to the substrate, to vary the wedge profile.

3. A method in accordance with claim 1, further comprising tilting the substrate with respect to the source, to change an exposure of the substrate to the sputter coating material, to vary the wedge profile.

4. A method in accordance with claim 1, further comprising placing a shield at a downstream side of the source, to selectively block the coating material following passage of the substrate past the source, to vary the wedge profile.

5. A method in accordance with claim 4, further comprising laterally shifting a position of the shield relative to the source, to vary the wedge profile.

6. A method in accordance with claim 1, further comprising adjusting a minimum linear distance between the target and the substrate.

7. A method in accordance with claim 1, wherein depositing the thin film of material on the substrate comprises depositing multiple discrete layers upon the substrate.

8. A method in accordance with claim 7, wherein depositing the thin film of material on the substrate comprises depositing a single metal layer between two dielectric layers.

9. A method in accordance with claim 1, wherein moving the substrate comprises moving a substrate having an array of photodiodes fabricated thereon, thereby depositing the thin film atop the photodibdes.

10. A system for fabricating a thin film filter, comprising:
a target, configured to disperse sputter coating material;
a mount, configured to hold and repeatedly move a substrate substantially linearly past the target; and
a shadow mask, positioned at a forward end of the mount, configured to block a portion of sputter coating material with each pass of the substrate, whereby the sputter coating material is deposited on the substrate in a wedge profile.

11. A system in accordance with claim 10, wherein a height of the mask relative to the mount is adjustable.

12. A system in accordance with claim 10, wherein the mask is oriented substantially perpendicular to the substrate.

13. A system in accordance with claim 10, further comprising a shield, positioned on a downstream side of the target, positioned to selectively block a flow of coating material toward the substrate following passage of the substrate past the source.

14. A system in accordance with claim 13, wherein a position of the shield relative to the target is adjustable.

15. A system in accordance with claim 10, wherein the mount is tiltable with respect to the target, to allow changing an exposure of the substrate to the target.

16. A system in accordance with claim 10, wherein a distance between the target and the mount is adjustable.

17. A thin film filter having a wedge profile, fabricated by a process of:
repeatedly moving a substrate, having a forward end, substantially linearly past a source of sputter coating material;
positioning a shadow mask adjacent to the forward end of the substrate, to selectively block the coating material with each pass of the substrate; and
depositing the sputter coating material on the substrate.

18. A thin film filter in accordance with claim 17, fabricated by a process further comprising at least one of the steps of (a) adjusting a height of the mask relative to the substrate, (b) tilting the substrate with respect to the source, (c) placing a shield at a downstream side of the source, and (d) adjusting a minimum linear distance between the target and the substrate, so as to vary the wedge profile.

19. A thin film filter in accordance with claim 17, wherein depositing the sputter coating material on the substrate further comprises depositing multiple discrete layers upon the substrate.

20. A thin film filter in accordance with claim 19, wherein depositing the sputter coating material on the substrate comprises depositing six alternating layers of two dielectric materials upon the substrate as a first dielectric stack, depositing one and only one metal layer upon the first dielectric stack, and depositing six alternating layers of the two dielectric materials upon the metal layer as a second dielectric stack.
